(19) United States
(12) Patent Application Publication
(10) Pub. No.: US 2024/0072088 A1
(43) Pub. Date: Feb. 29, 2024

(54) IMAGE SENSOR AND ELECTRONIC DEVICE INCLUDING THE SAME

(71) Applicant: SAMSUNG ELECTRONICS CO., LTD., SUWON-SI (KR)

(72) Inventor: EUNSUB SHIM, SUWON-SI (KR)

(21) Appl. No.: 18/223,649

(22) Filed: Jul. 19, 2023

(30) Foreign Application Priority Data
Aug. 31, 2022 (KR) 10-2022-0110322

(51) Int. Cl. H01L 27/146

(52) U.S. Cl. CPC H01L 27/14627; H01L 27/14621; H01L 27/14645

(57) ABSTRACT

An image sensor includes a shared pixel including a plurality of subpixels and a plurality of micro-lenses respectively disposed at upper portions of the plurality of subpixels. The shared pixel shares one color pattern, and a highest point of each of the plurality of micro-lenses is close to a center of the shared pixel.

### CROSS-REFERENCE TO RELATED APPLICATION(S)

A claim of priority under 35 U.S.C. § 119 is made to Korean Patent Application No. 10-2022-0110322, filed on Aug. 31, 2022, in the Korean Intellectual Property Office, the entirety of which is hereby incorporated by reference.

### BACKGROUND

The present disclosure relates to image sensors and electronic devices including the same, and more particularly to a structure of a micro-lens included in an image sensor.

Image sensors which capture an image and convert the image into an electrical signal are used in cameras equipped in vehicles, security devices, and robots for example as well as in general consumer electronic devices such as for example digital cameras, portable phone cameras, and portable camcorders. Such image sensors include a pixel array, and each pixel included in the pixel array may include a photodiode. Image sensors typically perform an auto focusing (AF) function so that an image is accurately captured for a short time.

### SUMMARY

Embodiments of the inventive concepts provide a micro-lens having a structure which may improve an auto focusing (AF) characteristic.

Embodiments of the inventive concepts provide an image sensor including a shared pixel including a plurality of subpixels; a plurality of micro-lenses respectively disposed at upper portions of the plurality of subpixels; and a color filter disposed between the shared pixel and the color filter. The color filter passes light of a single color to the shared pixel. Each of the plurality of subpixels includes two or more photodiodes. Highest points of each of the plurality of micro-lenses from an upper surface of the color filter are respectively disposed over one of the two or more photodiodes of the plurality of subpixels that are closer to a center of the shared pixel.

Embodiments of the inventive concepts further provide an image sensor including a shared pixel including first to n^{th} subpixels arranged in an N*N form; N*N number of first to n^{th} micro-lenses respectively disposed at upper portions of the first to n^{th} subpixels arranged in the N*N form; and a color filter disposed between the shared pixel and the first to n^{th} subpixels. A distance between a highest point of an m^{th} micro-lens from among the first to n^{th} micro-lenses as from an upper surface of the color filter and a center of the shared pixel is shorter than a distance between the center of the shared pixel and a center of an m^{th} subpixel from among the first to n^{th} subpixels that is disposed at a lower portion of the m^{th} micro-lens, and m is a natural number of 1 or more and n or less, n is a natural number of 4 or more, and N is a natural number of 2 or more.

Embodiments of the inventive concepts still further provide an electronic device including an image sensor; and a processor connected to the image sensor to process data of the image sensor. The image sensor includes a first subpixel including a first photodiode and a second photodiode; a second subpixel including a third photodiode and a fourth photodiode, the second subpixel disposed adjacent to the first subpixel; a first micro-lens disposed at an upper portion of the first subpixel; a second micro-lens disposed at an upper portion of the second subpixel; and a color filter disposed between the first and second subpixels and the first and second micro-lenses. A highest point of the first micro-lens from an upper surface of the color filter is disposed in a region over the second photodiode. A highest point of the second micro-lens from the upper surface of the color filter is disposed in a region over the third photodiode. The first and second subpixels form a shared pixel, the second photodiode is disposed closer to a center of the shared pixel than the first photodiode, and the third photodiode is disposed closer to the center of the shared pixel than the fourth photodiode.

### BRIEF DESCRIPTION OF THE DRAWINGS

The above and other aspects, features and advantages of the inventive concepts will be more clearly understood from the following detailed description taken in conjunction with the accompanying drawings, in which:

FIG. 1 illustrates a block diagram of a structure of an electronic device according to embodiments of the inventive concepts;

FIG. 2 illustrates a block diagram of an image sensor according to embodiments of the inventive concepts;

FIGS. 3A, 3B and 3C illustrate diagrams of implementation examples of a pixel array corresponding to a color filter array according to embodiments of the inventive concepts;

FIGS. 4A, 4B and 4C illustrate diagrams descriptive of a structure of a micro-lens according to embodiments of the inventive concepts;

FIGS. 5A, 5B and 5C illustrate diagrams descriptive of an effect of a micro-lens according to embodiments of the inventive concepts;

FIGS. 6A and 6B illustrate diagrams descriptive of data obtained by a micro-lens according to embodiments of the inventive concepts;

FIG. 7 illustrates a cross-sectional view descriptive of a structure of a micro-lens according to embodiments of the inventive concepts;

FIG. 8 illustrates a plan view of a micro-lens according to embodiments of the inventive concepts; and

FIG. 9 illustrates a plan view of a micro-lens according to other embodiments of the inventive concepts.

### DETAILED DESCRIPTION OF THE EMBODIMENTS

Hereinafter, various embodiments will be described with reference to the accompanying drawings. As is traditional in the field of the inventive concepts, embodiments may be described and illustrated in terms of blocks which carry out a described function or functions. These blocks, which may be referred to herein as units or modules or the like, are physically implemented by analog and/or digital circuits such as logic gates, integrated circuits, microprocessors, microcontrollers, memory circuits, passive electronic components, active electronic components, optical components, hardwired circuits and the like, and may optionally be driven by firmware and/or software. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the inventive concepts. Likewise, the blocks of the embodiments may be physically combined into more complex blocks without departing from the scope of the inventive concepts. Also, throughout the description, relative locations of components may be described using such terms as for example “vertical”, “horizontal”, “over”, “higher” and so on. These terms are for descriptive purposes only, and are intended only to describe the relative locations of components assuming the orientation of the overall device is the same as that shown in the drawings. The embodiments however should not be limited to the illustrated device orientations.

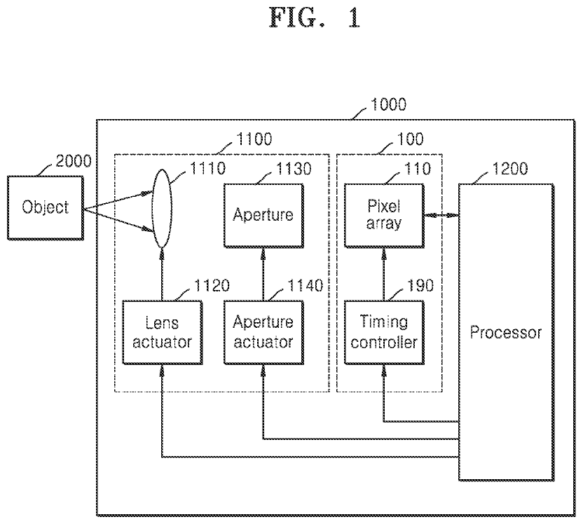

FIG. 1 illustrates a block diagram of a structure of an electronic device 1000 according to embodiments of the inventive concepts.

The electronic device 1000 according to embodiments may include an imaging unit 1100, an image sensor 100, and a processor 1200. The electronic device 1000 may have a focus detection function. The electronic device 1000 according to an embodiment may be an electronic device having an image or light sensing function. For example, the electronic device 1000 may be for example a camera, a smartphone, a wearable device, Internet of things (IoT), a tablet personal computer (PC), a personal digital assistant (PDA), a portable multimedia player (PMP), a navigation device or the like. For example, the electronic device 1000 may be a device which is provided as a part of a vehicle, furniture, manufacturing facilities, a door, and/or various measurement devices.

Operations of the electronic device 1000 may be controlled by the processor 1200. The processor 1200 may provide control signals to a lens actuator 1120, an aperture actuator 1140, and a timing controller 190 for operation of each element.

The imaging unit 1100 may be an element which receives light and may include a lens 1110, the lens actuator 1120, an aperture 1130, and the aperture actuator 1140. The lens 1110 may include a plurality of lenses.

The lens actuator 1120 may communicate with the processor 1200 to transfer and receive information about focus detection and may adjust a position of the lens 1110, based on the control signal provided from the processor 1200. The lens actuator 1120 may move the lens 1110 in a direction in which a distance to an object 2000 increases or decreases, and a distance between the lens 1110 and the object 2000 may be adjusted. A focus on the object 2000 may be matched or mismatched based on a position of the lens 1110.

The image sensor 100 may convert incident light into an image signal. The image sensor 100 may include a pixel array 110 and a timing controller 190. An optical signal passing through the lens 1110 and the aperture 1130 may reach a light receiving surface of the pixel array 110 to form a phase of a subject.

The pixel array 110 may include complementary metal oxide semiconductor image sensors (CIS) which convert an optical signal into an electrical signal. A sensitivity of the pixel array 110 may be adjusted by the timing controller 190. The pixel array 110 may include a plurality of pixels for performing an AF function or a distance measurement function.

The image sensor 100 may provide an image signal to the processor 1200, and the processor 1200 may perform a phase difference calculation by using the image signal. The processor 1200 may process data output from the image sensor 100. The processor 1200 may calculate an in-focus position, a focus direction, or a distance between the object 2000 and the image sensor 100, based on a result of the phase difference calculation. The processor 1200 may output the control signal to the lens actuator 1120 so as to move a position of the lens 1110, based on the result of the phase difference calculation.

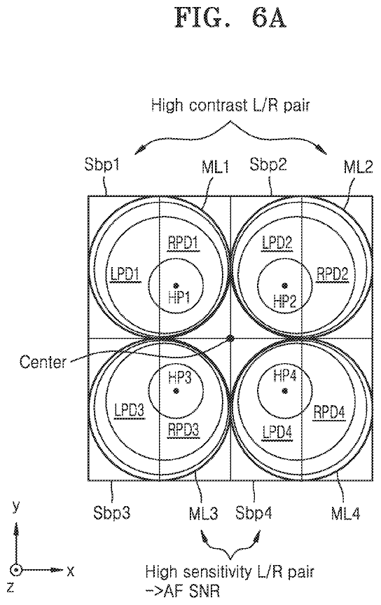

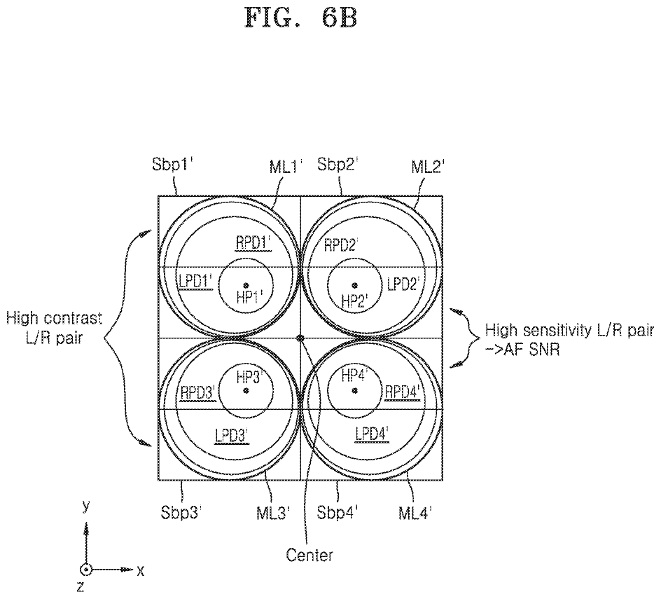

In an embodiment, the processor 1200 may classify electrical signals of a photodiode, applied from the pixel array 110, into a left-right data pair having high AF sensitivity and a left-right data pair having a high AF contrast. A criterion for classifying the electrical signals into the left-right data pair having high AF sensitivity and the left-right data pair having a high AF contrast may be changed based on a structure of a micro-lens of the pixel array 110 and an arrangement direction of a photodiode included in a subpixel arranged under the micro-lens. The processor 1200 may perform data processing based on a purpose by classifying the electrical signals applied from the pixel array 110. This will be described in detail with reference to FIGS. 6A and 6B.

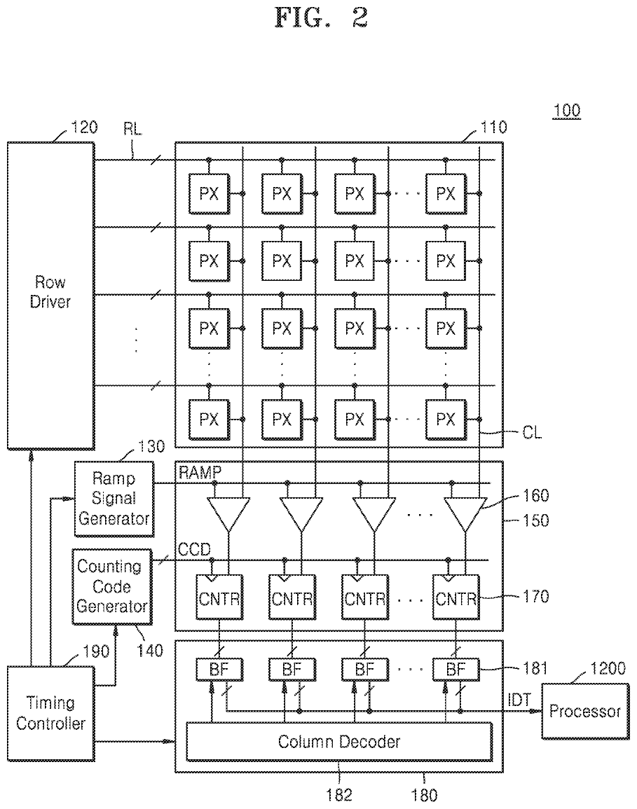

FIG. 2 illustrates a block diagram of an image sensor 100 according to embodiments of the inventive concepts.

Referring to FIG. 2, the image sensor 100 may include a pixel array 110, a row driver 120, a ramp signal generator 130, a counting code generator 140, an analog-to-digital conversion circuit 150 (hereinafter referred to as an ADC circuit), a data output circuit 180, and a timing controller 190. An element including the ADC circuit 150 and the data output circuit 180 may be referred to as a readout circuit. The pixel array 110 may include a plurality of row lines RL, a plurality of column lines CL, and a plurality of pixels PX. The plurality of pixels PX may be connected to the plurality of row lines RL and the plurality of column lines CL and may be arranged in a matrix form. The plurality of pixels PX may each include an active pixel sensor (APS).

Each of the plurality of pixels PX may include at least one photoelectric conversion device, and each pixel PX may sense light by using the photoelectric conversion device and may output an image signal which is an electrical signal based on the sensed light. For example, the photoelectric conversion device may include a photodiode, a phototransistor, or a photogate or a pinned photodiode. In an embodiment, an example where a photoelectric conversion device is a photodiode will be described.

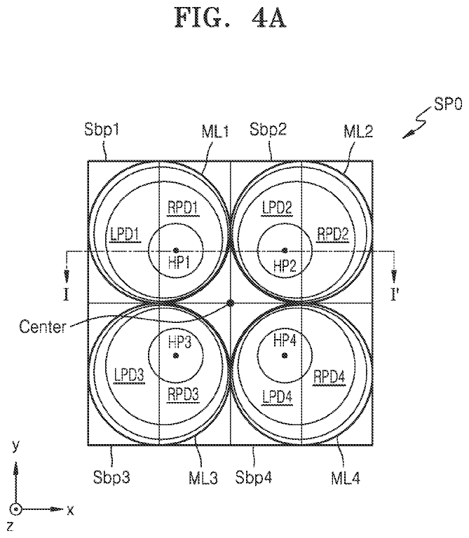

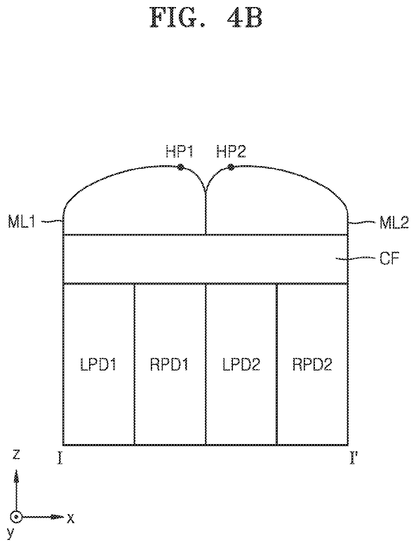

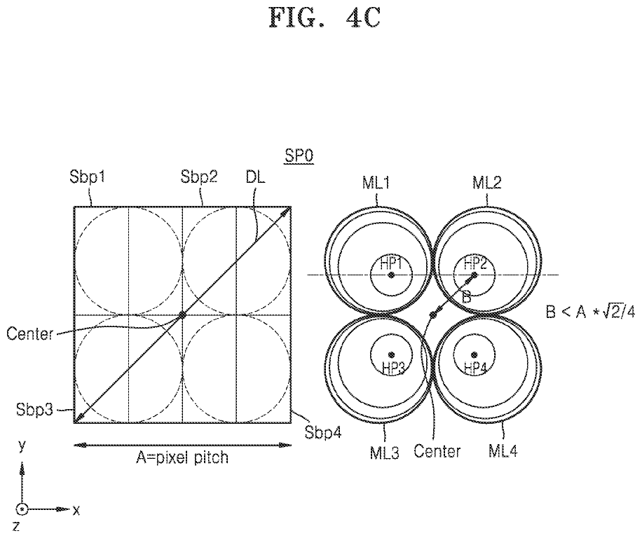

A micro-lens (see ML1 to ML4 of FIGS. 4A-4C which may be referred to collectively as FIG. 4) for collecting light may be disposed on each pixel PX, or on each of pixel groups each including adjacent pixels PX. Each of the plurality of pixels PX may sense light of a certain spectrum range from light received through the micro-lens (see ML1 to ML4 of FIG. 4) disposed thereon. A plurality of micro-lenses (see ML1 to ML4 of FIG. 4) of a shared pixel according to embodiments may have structure in which highest points of the micro-lenses are disposed close to the center point of the shared pixel. Based on the structure, characteristics of data based on an AF pixel may be maximized. This will be described below with reference to FIG. 4A.

The pixel array 110 may include at least one AF pixel. The AF pixel may be a pixel having a physical structure or a circuit for auto focusing. A plurality of micro-lenses (see ML1 to ML4 of FIG. 4) according to an embodiment may be micro-lenses arranged on the AF pixel.

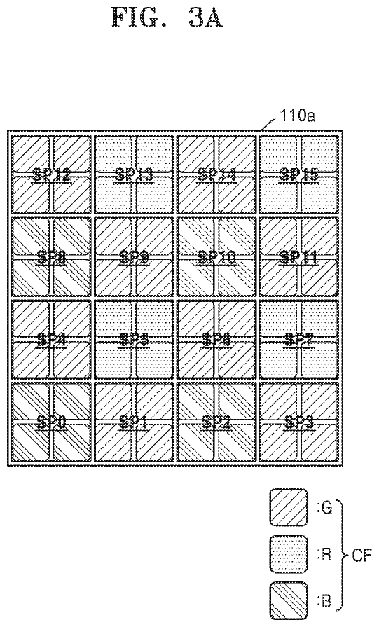

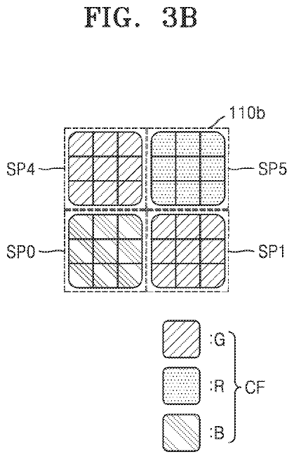

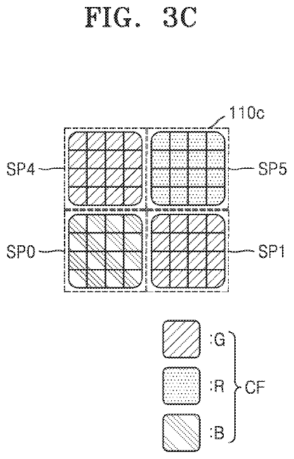

A color filter array (see CF of FIG. 3A) for transmitting light of a certain spectrum range may be disposed on a plurality of pixels PX, and a color sensed by a corresponding pixel may be determined based on a color filter disposed on each of the plurality of pixels PX. An arrangement structure between the color filter array and the plurality of pixels PX will be described below with reference to FIGS. 3A to 3C.

The row driver 120 may drive the pixel array 110 by row units. The row driver 120 may decode a row control signal (for example, an address signal) received from the timing controller 190 and may select at least one row line from among row lines configuring the pixel array 110 in response to the decoded row control signal. For example, the row driver 120 may generate a selection signal for selecting one row from among a plurality of rows. Also, the pixel array 110 may output a pixel signal (for example, a pixel voltage) through a row selected by the selection signal supplied from the row driver 120. The pixel signal may include a reset signal and an image signal. The row driver 120 may transfer, to the pixel array 110, control signals for outputting the pixel signal, and the pixel PX may operate in response to the control signals to output the pixel signal.

The ramp signal generator 130 may generate a ramp signal RAMP (for example, a ramp voltage) where a level thereof increases or decreases at a certain slope, based on control by the timing controller 190. The ramp signal RAMP may be supplied to each of a plurality of CDS (correlated double sampling) circuits 160 included in the ADC circuit 150.

The counting code generator 140 may generate a counting code CCD, based on control by the timing controller 190. The counting code CCD may be supplied to each of a plurality of counter circuits (CNTR) 170. In some embodiments, the counting code generator 140 may be implemented as a gray code generator. The counting code generator 140 may generate, as a counting code CCD, a plurality of code values having resolution based on the predetermined number of bits. For example, when a 10-bit code is set, the counting code generator 140 may generate the counting code CCD including 1,024 code values which sequentially increase or decrease.

The ADC circuit 150 may include a plurality of correlated double sampling (CDS) circuits 160 and a plurality of counter circuits 170. The ADC circuit 150 may convert a pixel signal (for example, a pixel voltage), input from the pixel array 110, into a pixel value which is a digital signal. Each of pixel signals respectively received through a plurality of column lines CL may be converted into a pixel value which is a digital signal, based on the CDS circuit 160 and the counter circuit 170.

The CDS circuit 160 may compare a pixel signal (for example, a pixel voltage), received through a corresponding column line CL, with the ramp signal RAMP and may output a comparison result as a comparison result signal. When a level of the ramp signal RAMP is the same as that of the pixel signal, the CDS circuit 160 may output a comparison signal which is shifted from a first level (for example, logic high) to a second level (for example, logic low). A time at which a level of the comparison signal is shifted may be determined based on a level of the pixel signal.

The CDS circuit 160 may sample the pixel signal supplied from the pixel PX, based on a CDS scheme. The CDS circuit 160 may sample a reset signal received as the pixel signal and may compare the reset signal with the ramp signal RAMP to generate a comparison signal based on the reset signal. Subsequently, the CDS circuit 160 may sample an image signal correlated with the reset signal and may compare the image signal with the ramp signal RAMP to generate a comparison signal based on the image signal.

The counter circuit 170 may count a level shift time of the comparison result signal output from the CDS circuit 160 and may output a count value. In some embodiments, the counter circuit 170 may include a latch circuit and a calculation circuit. The latch circuit may receive the counting code CCD from the counting code generator 140 and the comparison signal from the CDS circuit 160 and may latch a code value of the counting code CCD at a time at which a level of the comparison signal is shifted. The latch circuit may latch a code value (for example, a reset value) corresponding to the reset signal and a code value (for example, an image signal value) corresponding to the image signal, respectively. The calculation circuit may perform an arithmetic operation on the reset value and the image signal value to generate an image signal value from which a reset level of the pixel PX is removed. The counter circuit 170 may output, as a pixel value, the image signal value from which the reset level is removed.

The data output circuit 180 may temporarily store the pixel value output from the ADC circuit 150, and then, may output the stored pixel value. The data output circuit 180 may further include a plurality of column memories 181 and a column decoder 182. The column memory 181 may store the pixel value received from the counter circuit 170. In some embodiments, each of the plurality of column memories 181 may be included in the counter circuit 170. A plurality of pixel values respectively stored in the plurality of column memories 181 may be output as image data IDT, based on control by the column decoder 182.

The timing controller 190 may output the control signal to each of the row driver 120, the ramp signal generator 130, the counting code generator 140, the ADC circuit 150 (although not specifically shown in FIG. 2), and the data output circuit 180 to control operations or timings of the row driver 120, the ramp signal generator 130, the counting code generator 140, the ADC circuit 150, and the data output circuit 180.

The processor 1200 connected with the image sensor 100 may perform noise decrease (i.e., reduction) processing, gain adjustment, waveform standardization processing, interpolation processing, white balance processing, gamma processing, edge emphasis processing, and binning on the image data IDT. In some embodiments, the processor 1200 may be included in the image sensor 100.

FIGS. 3A to 3C illustrate diagrams of implementation examples of pixel arrays 110a, 110b, and 110c corresponding to a color filter array according to embodiments of the inventive concepts. FIGS. 3A-3C may be characterized as top plan views of pixel arrays.

Referring to FIG. 3A, the pixel array 110a may include a plurality of pixels arranged along a plurality of rows and columns, and for example, a shared pixel defined as a unit including pixels arranged in two rows and two columns may include four subpixels. The pixel array 110a may include first to sixteenth shared pixels SP0 to SP15. The pixel array 110a may further include a color filter array CF so that the first to sixteenth shared pixels SP0 to SP15 sense various colors. For example, the color filter array CF may include a plurality of filters which sense or pass red (R), green (G), and blue (B) light, and one of the first to sixteenth shared pixels SP0 to SP15 may include subpixels where the same color filter is provided. For example, the first shared pixel SP0, the third shared pixel SP2, the ninth shared pixel SP8, and the eleventh shared pixel SP10 may include subpixels including a blue (B) color filter and thus may sense blue light passed by the blue (B) color filters; the second shared pixel SP1, the fourth shared pixel SP3, the fifth shared pixel SP4, the seventh shared pixel SP6, the tenth shared pixel SP9, the twelfth shared pixel SP11, the thirteenth shared pixel SP12, and the fifteenth shared pixel SP14 may include subpixels including a green (G) color filter and thus may sense green light passed by the green (G) color filters; and the sixth shared pixel SP5, the eighth shared pixel SP7, the fourteenth shared pixel SP13, and the sixteenth shared pixel SP15 may include subpixels including a red (R) color filter and thus may sense red light passed by the red (R) color filters. Also, a group including the first shared pixel SP0, the second shared pixel SP1, the fifth shared pixel SP4, and the sixth shared pixel SP5; a group including the third shared pixel SP2, the fourth shared pixel SP3, the seventh shared pixel SP6, and the eighth shared pixel SP7; a group including the ninth shared pixel SP8, the tenth shared pixel SP9, the thirteenth shared pixel SP12, and the fourteenth shared pixel SP13; and a group including the eleventh shared pixel SP10, the twelfth shared pixel SP11, the fifteenth shared pixel SP14, and the sixteenth shared pixel SP15 may each be disposed in the pixel array 110a to correspond to a Bayer pattern. According to an embodiment, the group including the first shared pixel SP0, the second shared pixel SP1, the fifth shared pixel SP4, and the sixth shared pixel SP5; the group including the third shared pixel SP2, the fourth shared pixel SP3, the seventh shared pixel SP6, and the eighth shared pixel SP7; the group including the ninth shared pixel SP8, the tenth shared pixel SP9, the thirteenth shared pixel SP12, and the fourteenth shared pixel SP13; and the group including the eleventh shared pixel SP10, the twelfth shared pixel SP11, the fifteenth shared pixel SP14, and the sixteenth shared pixel SP15 may each correspond to a block of the color filter array CF.

However, this may be only an embodiment, and the pixel array 110a according to other embodiments may include various kinds of color filters. For example, the color filter array CF may include a plurality of filters which sense (or pass) yellow, cyan, magenta, and white, in addition to red, green, and blue. Also, the pixel array 110a may include more shared pixels, and the arrangement of the first to sixteenth shared pixels SP0 to SP15 may be variously implemented.

Referring to a pixel array 110b of FIG. 3B, each of a first shared pixel SP0, a second shared pixel SP1, a fifth shared pixel SP4, and a sixth shared pixel SP5 may include nine subpixels. The first shared pixel SP0 may include nine subpixels including a blue (B) color filter, and each of the second shared pixel SP1 and the fifth shared pixel SP4 may include nine subpixels including a green (G) color filter. The sixth shared pixel SP5 may include nine subpixels including a red (R) color filter. In some embodiments, the first shared pixel SP0, the second shared pixel SP1, the fifth shared pixel SP4, and the sixth shared pixel SP5 may be referred to as a nona cell.

Referring to a pixel array 110c of FIG. 3C, each of a first shared pixel SP0, a second shared pixel SP1, a fifth shared pixel SP4, and a sixth shared pixel SP5 may include sixteen subpixels. The first shared pixel SP0 may include sixteen subpixels including a blue (B) color filter, and each of the second shared pixel SP1 and the fifth shared pixel SP4 may include sixteen subpixels including a green (G) color filter. The sixth shared pixel SP5 may include sixteen subpixels including a red (R) color filter. In some embodiments, the first shared pixel SP0, the second shared pixel SP1, the fifth shared pixel SP4, and the sixth shared pixel SP5 may be referred to as a Hexadeca cell.

A shared pixel may include subpixels which include the same color filter and are adjacent to one another. The shared pixel illustrated in FIGS. 3A to 3C may be provided as an example which includes subpixels of an N*N array, but an array of subpixels included in a shared pixel is not limited to N*N. Here, N may be a natural number of 2 or more. Hereinafter, for convenience of description, a structure where a micro-lens is disposed at an upper portion of the shared pixel described above with reference to FIGS. 3A to 3C will be described as an example.

FIGS. 4A to 4C illustrate diagrams descriptive of a structure of a micro-lens according to embodiments of the inventive concepts.

FIG. 4A illustrates a top plan view of a structure where a micro-lens according to an embodiment is disposed at an upper portion of a shared pixel.

Referring to FIG. 4A, a shared pixel SP0 may include a first subpixel Sbp1, a second subpixel Sbp2, a third subpixel Sbp3, and a fourth subpixel Sbp4. The first subpixel Sbp1 and the second subpixel Sbp2 may be arranged adjacent to each other in an X-axis direction. The first subpixel Sbp1 and the third subpixel Sbp3 may be arranged adjacent to each other in a Y-axis direction. The second subpixel Sbp2 and the fourth subpixel Sbp4 may be arranged adjacent to each other in the Y-axis direction.

Each of the first subpixel Sbp1, the second subpixel Sbp2, the third subpixel Sbp3, and the fourth subpixel Sbp4 may include two photodiodes. The first subpixel Sbp1 may include a first photodiode LPD1 and a second photodiode RPD1. The second subpixel Sbp2 may include a first photodiode LPD2 and a second photodiode RPD2. The third subpixel Sbp3 may include a first photodiode LPD3 and a second photodiode RPD3. The fourth subpixel Sbp4 may include a first photodiode LPD4 and a second photodiode RPD4. The first photodiodes LPD1 to LPD4 and the second photodiodes RPD1 to RPD4 respectively included in the first subpixel Sbp1, the second subpixel Sbp2, the third subpixel Sbp3, and the fourth subpixel Sbp4 may be arranged adjacent to each other in the X-axis direction in a subpixel thereof. That is, for example, the first photodiodes LPD1 and RPD1 in the first sub-pixel Sbp1 may be arranged adjacent to each other in the X-axis direction.

A plurality of micro-lenses (for example, first to fourth micro-lenses) ML1 to ML4 may be arranged at an upper portion of the shared pixel SP0. The first micro-lens ML1 may be disposed at an upper portion of the first subpixel Sbp1. The second micro-lens ML2 may be disposed at an upper portion of the second subpixel Sbp2. The third micro-lens ML3 may be disposed at an upper portion of the third subpixel Sbp3. The fourth micro-lens ML4 may be disposed at an upper portion of the fourth subpixel Sbp4. Shapes of the first micro-lens ML1, the second micro-lens ML2, the third micro-lens ML3, and the fourth micro-lens ML4 may differ. For example in some embodiments a micro-lens may have one plane surface and another surface opposing the one plane surface, and the another surface may be spherical and may refract light. A highest point HP1 of the first micro-lens ML1, a highest point HP2 of the second micro-lens ML2, a highest point HP3 of the third micro-lens ML3, and a highest point HP4 of the fourth micro-lens ML4 may be disposed close to a center of the shared pixel SP0. In an embodiment, a highest point of a micro-lens may denote a position of a point at which the micro-lens has a greatest height in a Z-axis direction, measured for example from an upper surface of the photodiodes LPD and RPD. In an embodiment, a lowest point of a micro-lens may denote a position of a point at which the micro-lens has a smallest height in the Z-axis direction, measured for example from an upper surface of color filter array CF. In FIG. 4A, the concentric circles in each of the subpixels may represent contour lines that indicate relative height of the micro-lenses from the upper surface of a color filter array CF (e.g., see FIG. 4B) along the Z-axis direction. For example, the height of a micro-lens may be greatest at the corresponding HP and may be lowest near the edges of a subpixel.

As shown in FIG. 4A, a highest point HP1 of the first micro-lens ML1 may be disposed in a region where the second photodiode RPD1 from among the first photodiode LPD1 and the second photodiode RPD1 each included in the first subpixel Sbp1 is provided. A highest point HP2 of the second micro-lens ML2 may be disposed in a region where the first photodiode LPD2 from among the first photodiode LPD2 and the second photodiode RPD2 each included in the second subpixel Sbp2 is provided. A highest point HP3 of the third micro-lens ML3 may be disposed in a region where the second photodiode RPD3 from among the first photodiode LPD3 and the second photodiode RPD3 each included in the third subpixel Sbp3 is provided. A highest point HP4 of the fourth micro-lens ML4 may be disposed in a region where the first photodiode LPD4 from among the first photodiode LPD4 and the second photodiode RPD4 each included in the fourth subpixel Sbp4 is provided. In other words and for example, the highest point HP1 of the first micro-lens ML1 at the first subpixel Sbp1 may be disposed in a region above second photodiode RPD1, not in a region above first photodiode LPD1.

Referring further to FIG. 4A, a plurality of micro-lenses ML1 to ML4 included in a shared pixel SP0 may thus have a structure in which the highest points HP are close to (e.g., over) one photodiode from among first photodiodes LPD1 to LPD4 and second photodiodes RPD1 to RPD4 respectively included in subpixels Sbp1 to Sbp4 disposed at a lower portion of each of the micro-lenses ML1 to ML4. In particular, the plurality of micro-lenses (for example, first to fourth micro-lenses) ML1 to ML4 included in the shared pixel SP0 may have a structure in which the highest points HP are close to (e.g., over) a photodiode disposed close (i.e., closer) to a center of the first photodiodes LPD1 to LPD4 and the second photodiodes RPD1 to RPD4 respectively included in the subpixels Sbp1 to Sbp4 at a lower portion of each of the micro-lenses ML1 to ML4. For example, in subpixel Sbp1, the highest point HP1 is disposed over the second photodiode RPD1, which is the photodiode from among photodiodes RPD1 and LPD1 in subpixel Sbp1 that is closer to the center of shared pixel Sp0.

The first micro-lens ML1 and the fourth micro-lens ML4 may be symmetric with each other with respect to the center of the shared pixel SP0. The second micro-lens ML2 and the third micro-lens ML3 may be symmetric with each other with respect to the center of the shared pixel SP0. Referring to FIG. 4A, micro-lenses facing each other in either the X-axis direction or the Y-axis direction may be provided as having symmetric structure with respect to each other. For example, the structures of micro-lenses ML1 and ML3 may be symmetric to each other along the Y-axis direction.

FIG. 4B illustrates a cross-sectional view, taken along line I-I′, of the image sensor of FIG. 4A.

Referring to FIG. 4B, a cross-sectional view is illustrated where a color filter array CF, the first micro-lens ML1, and the second micro-lens ML2 are disposed at upper portions of the first subpixel Sbp1 and the second subpixel Sbp2.

Referring to FIG. 4B, the first micro-lens ML1 and the second micro-lens ML2 may be symmetric with each other along the X-axis direction. The first micro-lens ML1 may have a structure in which the highest point HP1 is over (or overlaps) the second photodiode RPD1 (which is the rightmost photodiode of the first subpixel Sbp1). The second micro-lens ML2 may have a structure in which the highest point HP2 is over (or overlaps) the first photodiode LPD2 (which is the leftmost photodiode of the second subpixel Sbp2). A height of a highest point HP1 of the first micro-lens ML1 may be the same as that of a highest point HP2 of the second micro-lens ML2.

FIG. 4C illustrates a diagram descriptive of a length condition between a shared pixel and a highest point of a micro-lens disposed at an upper portion of the shared pixel according to embodiments of the inventive concepts. In FIG. 4C, for convenience of description, subpixels Sbp1 to Sbp4 are depicted apart from micro-lenses ML1 to ML4 so that micro-lenses ML1 to ML4 do not overlap subpixels Sbp1 to Sbp4.

Referring to FIG. 4C, a length of a shared pixel SP0 including four subpixels Sbp1 to Sbp4 in an X-axis direction may be A. A may denote a pixel pitch.

Referring to FIG. 4C, the four subpixels Sbp1 to Sbp4 and four micro-lenses ML1 to ML4 respectively disposed at upper portions of the four subpixels Sbp1 to Sbp4 are illustrated. A distance between each of positions of highest points HP1 to HP4 of the four micro-lenses ML1 to ML4 and a center of the shared pixel SP0 may be B. According to an embodiment, the distance B between each of the positions of the highest points HP1 to HP4 of the four micro-lenses (for example, first to fourth micro-lenses) ML1 to ML4 and the center of the shared pixel SP0 may denote a rectilinear distance which is measured at the same height of the same plane. According to an embodiment, a relationship between A and B may be expressed as the following Equation.

$$B < A * \frac{\sqrt{2}}{4}$$

According to an embodiment, when a length of the shared pixel SP0 in the X-axis direction is A, a length of the shared pixel SP0 in a Y-axis direction may also be A. A diagonal length of a diagonal line DL connecting a line of the shared pixel SP0 in the X-axis direction with a line of the shared pixel SP0 in the Y-axis direction may be A*\sqrt{2}. Diagonal line DL connecting a line of the shared pixel SP0 in the X-axis direction with a line of the shared pixel SP0 in the Y-axis direction may pass through a region where the second micro-lens ML2 and the third micro-lens ML3 are provided. When the four micro-lenses ML1 to ML4 included in the shared pixel SP0 have the same curvature and are arranged in a complete semispherical shape, a value of

$$A * \frac{\sqrt{2}}{4}$$

may denote a distance between a center of the shared pixel SP0 and a center of a micro-lens, and a value of

$$A * \frac{\sqrt{2}}{4}$$

may denote a distance between the center of the shared pixel SP0 and a center of a subpixel disposed at a lower portion of the micro-lens.

Referring to FIG. 4C, a distance B between the center of the shared pixel SP0 and each of highest points HP1 to HP4 of a micro-lens according to an embodiment may have a value which is less than

$$A * \frac{\sqrt{2}}{4} .$$

That is, the highest points HP1 to HP4 of the micro-lens according to an embodiment may be disposed close to the center of the shared pixel SP0.

A structure of the micro-lens according to an embodiment may include a plurality of photodiodes included in each of subpixels of a shared pixel sharing the same color pattern, and may be applied to a case where each of a plurality of subpixels includes a number of micro-lenses corresponding thereto.

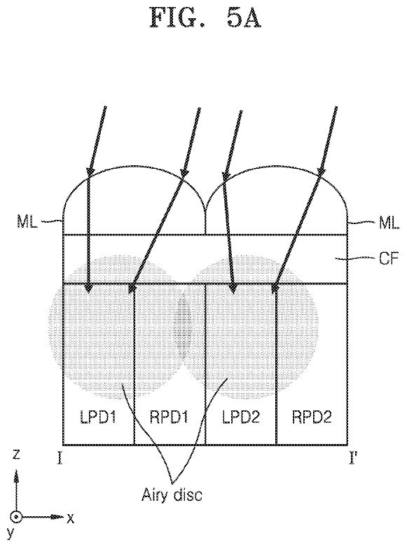

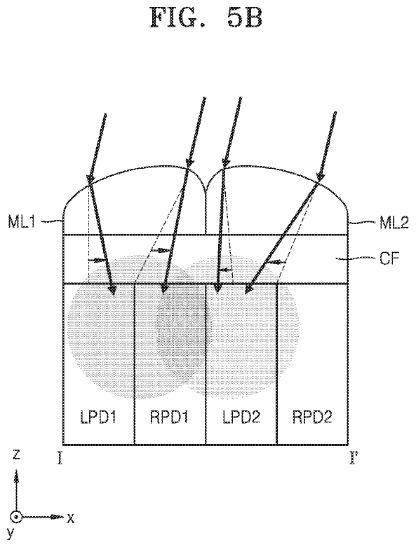

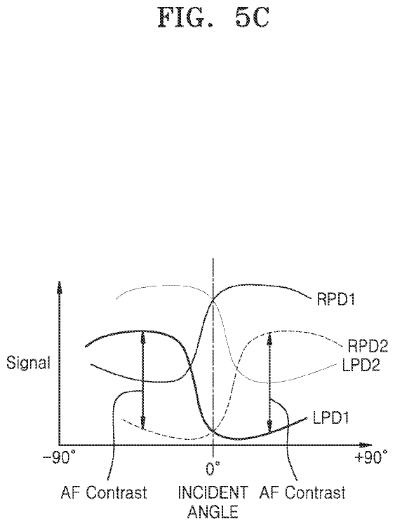

FIGS. 5A to 5C illustrate diagrams descriptive of an effect of a micro-lens according to embodiments of the inventive concepts.

FIG. 5A illustrates a diagram descriptive of transmission of light by a micro-lens according to a comparative example.

Referring to FIG. 5A, a structure is illustrated where two micro-lenses ML having a complete semispherical shape and the same curvature are disposed at an upper portion of a subpixel including two photodiodes. The highest points of the micro-lenses ML are respectively over the interface between first photodiode LPD1 and second photodiode RPD1, and the interface between first photodiode LPD2 and second photodiode RPD2. Referring to the comparative example of FIG. 5A, respective airy disks caused by incident light may be largely formed due to this configuration, and due to crosstalk it may be unclear and difficult to classify left and right electrical signals of an AF pixel. Also referring to FIG. 5A, there may for example be a signal transferred from first photodiode LPD1 to an adjacent pixel (not shown), and due to this there may be a possibility that resolution is reduced. For example, an airy disk may be characterized as a best-focused spot of light that a lens can make, and may have a central disk having a local maxima surrounded by less intense concentric rings away from the center.

FIG. 5B illustrates s a diagram descriptive of transmission of light when a structure of the micro-lens in FIG. 4B is provided. In contrast to the comparative example described with respect to FIG. 5A, according to FIG. 5B a path through which light is applied to a photodiode through a structure of micro-lenses ML1 and ML2 is close to a center of a shared pixel. For convenience of description, the transmission path of light by a structure of FIG. 5A is illustrated by dashed line in FIG. 5B.

Referring to FIG. 5B, in a region corresponding to a first photodiode LPD1 of a first micro-lens ML1, light may be applied in a direction closer to the right, compared to FIG. 5A. In a region corresponding to a second photodiode RPD1 of the first micro-lens ML1, light may be applied in a direction closer to the left, compared to FIG. 5A.

Referring to FIG. 5B, in a region corresponding to a first photodiode LPD2 of a second micro-lens ML2, light may be applied in a direction closer to the left, compared to FIG. 5A. In a region corresponding to a second photodiode RPD2 of the second micro-lens ML2, light may be applied in a direction closer to the left, compared to FIG. 5A.

Referring to FIG. 5B, the first micro-lens ML1 may have a structure in which the highest point HP1 (e.g., see FIG. 4A) is close to the right side of the subpixel including photodiodes LPD1 and RPD1 which is a direction toward the center of a shared pixel, and the light transmitted through the first micro-lens ML1 may therefore be applied more toward the right side direction as compared to FIG. 5A. The second micro-lens ML2 may have a structure in which the highest point HP2 (e.g., see FIG. 4A) is close to the left side of the subpixel including photodiodes LPD2 and RPD2 which is a direction toward the center of the shared pixel, and the light transmitted through second micro-lens ML2 may therefore be applied more toward the left side direction as compared to FIG. 5A.

Based on such a structure, light passing through the first micro-lens ML1 and the second micro-lens ML2 may be applied toward a center of the shared pixel. The second photodiode RPD1 included in the first micro-lens ML1 and the first photodiode LPD2 included in the second micro-lens ML2 may each be a photodiode which is disposed at or near a center portion of the shared pixel. Therefore, the amount of light applied to the second photodiode RPD1 included in the first micro-lens ML1 and the first photodiode LPD2 included in the second micro-lens ML2 may increase, and thus pieces of data based on the second photodiode RPD1 and the first photodiode LPD2 may be left and right data in which a sensitivity of an AF pixel is secured. The amount of light applied to the first photodiode LPD1 included in the first micro-lens ML1 and the second photodiode RPD2 included in the second micro-lens ML2 may be less than the amount of light applied to the second photodiode RPD1 included in the first micro-lens ML1 and the first photodiode LPD2 included in the second micro-lens ML2, but however pieces of data based thereon may be left and right data where an AF contrast is high.

FIG. 5C illustrates a graph showing a sensitivity of a signal based on each of the first photodiode LPD1 and the second photodiode RPD1 disposed at a lower portion of the first micro-lens ML1, and the first photodiode LPD2 and the second photodiode RPD2 disposed at a lower portion of the second micro-lens ML2, with respect to an incident angle. The X axis of the graph of FIG. 5C denotes an incident angle, and the Y axis denotes a sensitivity of a signal. The incident angle of the X axis of the graph may have a range of −90 to +90 with respect to 0 degrees. In the graph of FIG. 5C, an AF contrast may denote a magnitude between a minimum sensitivity and a maximum sensitivity between signals output from photodiodes. It may be seen that the AF contrast increases as a magnitude between the maximum sensitivity and the minimum sensitivity increases.

Referring to FIG. 5C, it may be seen that a signal of the second photodiode RPD1 disposed at the lower portion of the first micro-lens ML1 and a signal of the first photodiode LPD2 disposed at the lower portion of the second micro-lens ML2 have a highest sensitivity at incident angles opposite to each other. Accordingly, pieces of data of a corresponding electrical signal may be used as a left-right data pair associated with a sensitivity of the AF pixel.

Referring to FIG. 5C, a magnitude between a maximum value of a signal of the first photodiode LPD1 disposed at the lower portion of the first micro-lens ML1 and a minimum value of a signal of the second photodiode RPD2 disposed at the lower portion of the second micro-lens ML2 may be used as an AF contrast value. Accordingly, pieces of data of a corresponding electrical signal may be used as a left-right data pair associated with a contrast of the AF pixel.

FIGS. 6A and 6B illustrate diagrams descriptive of data obtained by a micro-lens according to embodiments of the inventive concepts.

Referring to FIG. 6A, a top plan view of an image sensor including micro-lenses ML1 to ML4 disposed at an upper portion of a shared pixel SP0 including four subpixels Sbp1 to Sbp4 is provided. This may be the same as a structure illustrated in FIG. 4A, and thus repeated descriptions of structure may be omitted from the following.

Referring to FIG. 6A, pieces of data of electrical signals applied to a second photodiode RPD1 of a first subpixel Sbp1 disposed at a right direction thereof with respect to the X-axis direction, a first photodiode LPD2 of a second subpixel Sbp2 disposed at a left direction thereof with respect to the X-axis direction, a second photodiode RPD3 of a third subpixel Sbp3 disposed at a right direction thereof with respect to the X-axis direction, and a first photodiode LPD4 of a fourth subpixel Sbp4 disposed at a left direction thereof with respect to the X-axis direction may be data pairs where AF sensitivity is high. In this case, pieces of data of electrical signals applied to the second photodiode RPD1 and the first photodiode LPD2 may be classified into a left-right data pair, and pieces of data of electrical signals applied to the second photodiode RPD3 and the first photodiode LPD4 may be classified into a left-right data pair.

Referring further to FIG. 6A, pieces of data of electrical signals applied to a first photodiode LPD1 of the first subpixel Sbp1 disposed at the left direction thereof with respect to the X-axis direction, a second photodiode RPD2 of a second subpixel Sbp2 disposed at a right direction thereof with respect to the X-axis direction, a first photodiode LPD3 of the third subpixel Sbp3 disposed at a left direction thereof with respect to the X-axis direction, and a second photodiode RPD4 of the fourth subpixel Sbp4 disposed at a right direction thereof with respect to the X-axis direction may be data pairs where an AF contrast is high. In this case, pieces of data of electrical signals applied to the first photodiode LPD1 and the second photodiode RPD2 may be classified into a left-right data pair, and pieces of data of electrical signals applied to the first photodiode LPD3 and the second photodiode RPD4 may be classified into a left-right data pair.

Referring to FIG. 6B, a case is illustrated in top plan view where photodiodes included in a plurality of subpixels Sbp1′ to Sbp4′ included in a shared pixel are arranged in a direction which differs from FIG. 6A. Referring to FIG. 6B, first photodiodes LPD1′ to LPD4′ and second photodiodes RPD1′ to RPD4′ respectively included in the subpixels Sbp1′ to Sbp4′ may be arranged in parallel in a Y-axis direction in the subpixels (for example, first to fourth subpixels) Sbp1′ to Sbp4′. For example, in FIG. 6B first photodiode LPD1′ and second photodiode RPD1′ of first subpixel Sbp1′ are arranged next to each other in the Y-axis direction, while in FIG. 6A first photodiode LPD1 and second photodiode RPD2 of first subpixel Sbp1 are in contrast arranged next to each other in the X-axis direction.

Referring to FIG. 6B, pieces of data of electrical signals applied to a first photodiode LPD1′ disposed at a portion of the first subpixel Sbp1′ that is adjacent to the center point of the shared pixel in the Y-axis direction, a first photodiode LPD2′ disposed at a portion of the second subpixel Sbp2′ that is adjacent to the center point of the shared pixel in the Y-axis direction, a second photodiode RPD3′ disposed at a portion of the third subpixel Sbp3′ that is adjacent to the center point of the shared pixel in the Y-axis direction, and a second photodiode RPD4′ disposed at a portion of the fourth subpixel Sbp4′ that is adjacent to the center point of the shared pixel in the Y-axis direction may be data pairs where AF sensitivity is high.

Referring further to FIG. 6B, pieces of data of electrical signals applied to a second photodiode RPD1′ disposed at a portion of the first subpixel Sbp1′ that is not adjacent to the center point of the shared pixel in the Y-axis direction, a second photodiode RPD2′ disposed at a portion of the second subpixel Sbp2′ that is not adjacent to the center point of the shared pixel in the Y-axis direction, a first photodiode LPD3′ disposed at a portion of the third subpixel Sbp3′ that is not adjacent to the center point of the shared pixel in the Y-axis direction, and a first photodiode LPD4′ disposed at a r portion of the fourth subpixel Sbp4′ that is not adjacent to the center point of the shared pixel in the Y-axis direction may be data pairs where an AF contrast is high.

Referring to FIGS. 6A and 6B, photodiodes for determining a data pair having high AF sensitivity and a data pair having a high AF contrast may be changed based on a direction in which photodiodes included in a subpixel are arranged. According to an embodiment, electrical signals applied to photodiodes adjacent to a center of a shared pixel may be classified into left-right data pairs having high AF sensitivity, and electrical signals applied to photodiodes which are not adjacent to the center of the shared pixel may be classified into a left-right data pair having a high AF contrast.

The processor 1200 of FIG. 1 may analyze or process pieces of data of the electrical signals based on a purpose (e.g., adjusting AF sensitivity or adjusting AF contrast). According to n embodiments, when adjusting AF sensitivity the processor 1200 may apply corresponding pieces of data from data pairs of the shared pixel having high AF sensitivity. According to embodiments, when adjusting AF contrast the processor 1200 may apply corresponding pieces of data from data pairs of the shared pixel having a high AF contrast.

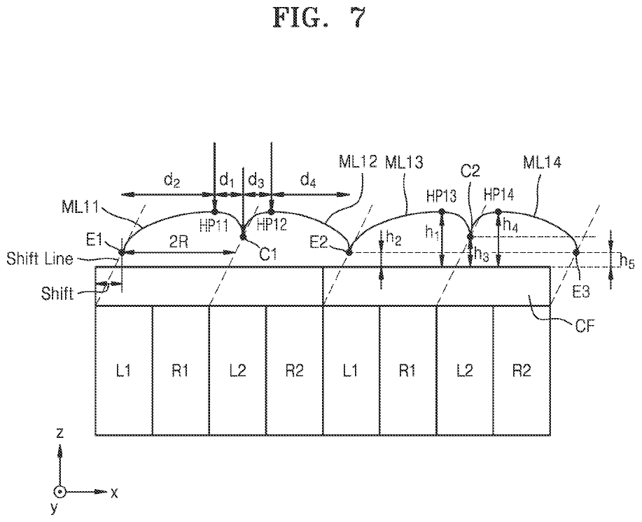

FIG. 7 illustrates a cross-sectional view descriptive of a structure of a micro-lens according to embodiments of the inventive concepts.

Referring to FIG. 7, two cross-sectional views of shared pixels arranged in parallel in an X-axis direction are illustrated. Referring to FIG. 7, a plurality of micro-lenses ML11 to ML14 disposed at an upper portion of the shared pixels may be provided over corresponding photodiodes L1, R1, L2 and R2. For example, in FIG. 7 a first shared pixel may include micro-lens ML11 over photodiodes L1 and R1 as a subpixel, and micro-lens ML12 over photodiodes L2 and R2 as another subpixel. Similarly, a second shared pixel in FIG. 7 may include micro-lens ML13 over photodiodes L1 and R1 as a subpixel, and micro-lens ML14 over photodiodes L2 and R2 as another subpixel. As shown, the color filter array CF is disposed between the plurality of micro-lenses and the photodiodes similarly as described with respect to FIG. 4B for example.

Referring to FIG. 7, the plurality of micro-lenses ML11 to ML14 disposed at the upper portion of the shared pixel may be shifted and arranged in the X-axis direction. The plurality of micro-lenses ML11 to ML14 may be shifted and arranged in the X-axis direction along a shift line. Arrangement positions of the plurality of micro-lenses ML11 to ML14 may be changed based on a relative position with respect to a lens (e.g., 1110 of FIG. 1) of an imaging unit (e.g., 1100 of FIG. 1). Positions of the plurality of micro-lenses ML11 to ML14 may be shifted toward a center of the lens (e.g., 1110 of FIG. 1) as the plurality of micro-lenses (for example, first to fourth micro-lenses) ML11 to ML14 are farther away from the center of the lens (e.g., 1110 of FIG. 1).

Referring to FIG. 7, a distance d1 in the X-axis direction between a highest point HP11 of the first micro-lens ML11 and a center C1 of the shared pixel may have a value which is less than a distance d2 in the X-axis direction between the highest point HP11 of the first micro-lens ML11 and an edge E1 of the shared pixel. A distance d3 in the X-axis direction between a highest point HP12 of the second micro-lens ML12 and the center C1 of the shared pixel may have a value which is less than a distance d4 in the X-axis direction between the highest point HP12 of the second micro-lens ML12 and an edge E2 of the shared pixel. According to an embodiment, the distance d1 in the X-axis direction between the highest point HP11 of the first micro-lens ML11 and the center C1 of the shared pixel, and the distance d3 in the X-axis direction between the highest point HP12 of the second micro-lens ML12 and the center C1 of the shared pixel may have the same value. According to an embodiment, a diameter of the first micro-lens ML11 may be 2R. The distance d1 in the X-axis direction between the highest point HP11 of the first micro-lens ML11 and the center C1 of the shared pixel may have a value which is less than R.

Referring to FIG. 7, a height h1 of a highest point HP13 of the third micro-lens ML13 may be the same as a height h4 of a highest point HP14 of the fourth micro-lens ML14. A height h2 of a lowest point E2 of the third micro-lens ML13 may be the same as a height h5 of a lowest point E3 of the fourth micro-lens ML14. A height h2 of a lowest point at an edge E2 of the third micro-lens ML13 may be different than a height h3 of a lowest point at a center C2 of the shared pixel including the fourth micro-lens ML14. The height h2 of the lowest point at the edge E2 of the third micro-lens ML13 may be lower than the height h3 of the lowest point at the center C2 of the shared pixel including the fourth micro-lens ML14. In FIG. 7, the heights may be taken as measured from an upper surface of the color filter array CF.

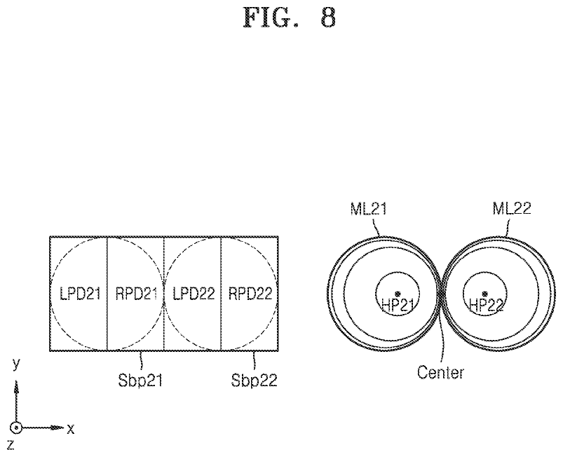

FIG. 8 illustrates a plan view of a micro-lens according to n embodiments of the inventive concepts. In FIG. 8, for convenience of description, subpixels Sbp21 and Sbp22 are depicted apart from micro-lenses ML21 and ML22 so that micro-lenses ML21 and ML22 do not overlap subpixels Sbp21 and Sbp22.

Referring to FIG. 8, a shared pixel may include two subpixels Sbp21 and Sbp22. The two subpixels Sbp21 and Sbp22 may include first photodiodes LPD21 and LPD22 and second photodiodes RPD21 and RPD22.

Referring to FIG. 8, a first micro-lens ML21 and a second micro-lens ML22 respectively disposed at upper portions of the two subpixels (for example, first and second subpixels) Sbp21 and Sbp22 may have a symmetric structure therebetween.

According to the embodiment of FIG. 8, a shared pixel may include a number of subpixels Sbp21 and Sbp22 instead of an N*N number, and a detailed shape of a micro-lens may be changed based on the number of subpixels included in the shared pixel. The first micro-lens ML21 and the second micro-lens ML22 may be symmetric with each other with respect to a center of the shared pixel.

In FIG. 8, a highest point HP21 of the first micro-lens ML21 and a highest point HP22 of the second micro-lens ML22 may be disposed on the same line as the center of the shared pixel, but the inventive concept is not limited thereto. The highest point HP21 of the first micro-lens ML21 and the highest point HP22 of the second micro-lens ML22 may be disposed on a line which differs from the center of the shared pixel. The highest point HP21 of the first micro-lens ML21 may be disposed in a region corresponding to a right photodiode RPD21 of the first subpixel Sbp21, and the highest point HP22 of the second micro-lens ML22 may be disposed in a region corresponding to a left photodiode LPD22 of the second subpixel Sbp22.

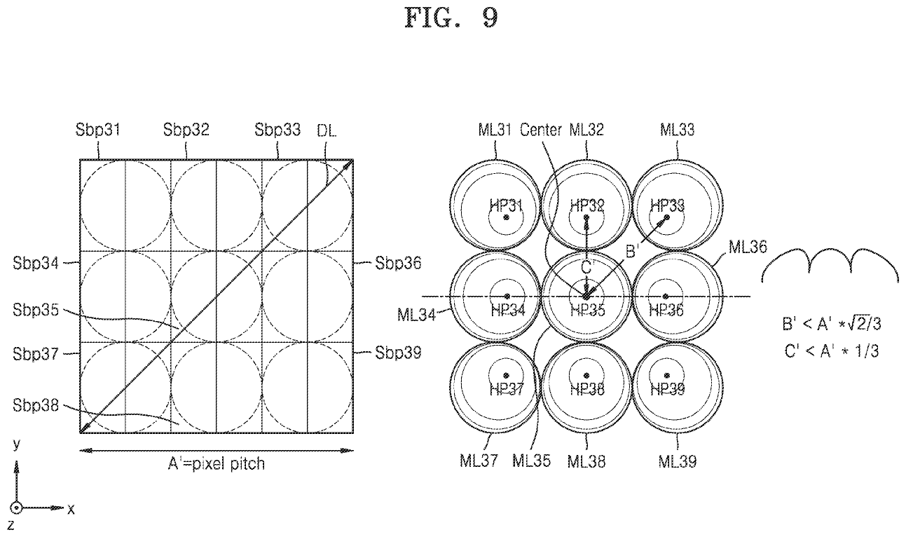

FIG. 9 illustrates a plan view of a micro-lens according to embodiments of the inventive concepts. In FIG. 9, for convenience of description, subpixels Sbp31 to Sbp39 are depicted apart from micro-lenses (for example, first to ninth micro-lenses) ML31 to ML39 so that micro-lenses ML31 to ML39 do not overlap subpixels Sbp31 to Sbp39.

Referring to FIG. 9, 3*3 subpixels Sbp31 to Sbp39 and 3*3 micro-lenses ML31 to ML39, which are respectively disposed at upper portions of the subpixels Sbp31 to Sbp39 and correspond to the number of subpixels, may be provided as a shared pixel. Each of the 3*3 subpixels Sbp31 to Sbp39 may include two photodiodes.

Referring to FIG. 9, the first micro-lens ML31, the third micro-lens ML33, the seventh micro-lens ML37, and the ninth micro-lens ML39 may be micro-lenses which are arranged adjacent to the fifth micro-lens ML35 that is disposed at a center of the shared pixel in a diagonal direction. The second micro-lens ML32, the fourth micro-lens ML34, the sixth micro-lens ML36, and the eighth micro-lens ML38 may be micro-lenses which are arranged adjacent to the fifth micro-lens ML35 that is disposed at the center of the shared pixel in either of an X-axis direction or a Y-axis direction.

B′ illustrated in FIG. 9 may denote a distance between a center HP35 of the fifth micro-lens ML35 that is disposed at the center of the shared pixel, and a highest point HP31 of the first micro-lens ML31 or a highest point HP33 of the third micro-lens ML33 or a highest point HP37 of the seventh micro-lens ML37 or a highest point HP39 of the ninth micro-lens ML39.

C′ illustrated in FIG. 9 may denote a distance between the center HP35 of the fifth micro-lens ML35 that is disposed at the center of the shared pixel, and a highest point HP32 of the second micro-lens ML32 or a highest point HP34 of the fourth micro-lens ML34 or a highest point HP36 of the sixth micro-lens ML36 or a highest point HP38 of the eighth micro-lens ML38.

A length of the shared pixel in the X-axis direction may be A′. A relationship between A′ and B′ may be expressed as the following Equation.

$${B}^{′} < {A}^{′} * \frac{\sqrt{2}}{3}$$

According to an embodiment, when the length of the shared pixel in the X-axis direction is A′, a length of the shared pixel in the Y-axis direction may also be A′. A diagonal length of line DL connecting a line of the shared pixel in the X-axis direction with a line of the shared pixel in the Y-axis direction may be A′*\sqrt{2}. The diagonal line DL connecting a line in the X-axis direction of the shared pixel with a line in the Y-axis direction may pass through a region where the third micro-lens ML33 and the fifth micro-lens ML35 and the seventh micro-lens ML37 are provided. When nine micro-lenses included in a shared pixel have the same curvature and are arranged in a complete semispherical shape, a value of

$${A}^{′} * \frac{\sqrt{2}}{3}$$

may denote a distance between a center of the shared pixel and a center of a micro-lens disposed at a diagonal line. A value of

$${A}^{′} * \frac{\sqrt{2}}{3}$$

may denote a distance between the center of the shared pixel and a center of a subpixel disposed at a lower portion of a micro-lens disposed on a diagonal line with respect to the shared pixel.

Referring to FIG. 9, a distance B′ between a center of a shared pixel according to an embodiment and a highest point of a micro-lens adjacent to a micro-lens disposed at the center of the shared pixel in a diagonal direction may have a value which is less than

$${A}^{′} * \frac{\sqrt{2}}{3} .$$

That is, a highest point of a micro-lens according to an embodiment may be disposed close to the center of the shared pixel.

A length of the shared pixel in the X-axis direction may be A′. A relationship between A′ and C′ may be expressed as the following Equation.

$${C}^{′} < {A}^{′} * \frac{1}{3}$$

According to an embodiment, when the length of the shared pixel in the X-axis direction is A′, a length of the shared pixel in the Y-axis direction may also be A′. When nine micro-lenses included in a shared pixel have the same curvature and are arranged in a complete semispherical shape, a value of

$${A}^{′} * \frac{1}{3}$$

may denote a distance between the center of the shared pixel and a center of a micro-lens disposed adjacent thereto in either of an X-axis direction and a Y-axis direction. A value of

$${A}^{′} * \frac{1}{3}$$

may denote a distance between the center of the shared pixel and a center of a subpixel disposed at a lower portion of a micro-lens disposed adjacent thereto in the X-axis direction and the Y-axis direction.

Referring to FIG. 9, a distance C′ between a center of a shared pixel according to an embodiment and a highest point of a micro-lens adjacent to a micro-lens disposed at the center of the shared pixel in either of the X-axis direction and the Y-axis direction may have a value which is less than

$${A}^{′} * \frac{1}{3} .$$

That is, a highest point of a micro-lens according to an embodiment may be disposed close to the center of the shared pixel.

Referring to the embodiment of FIG. 9, in a pixel array including a plurality of micro-lenses, when there is a subpixel Sbp35 including a center of a shared pixel, a highest point HP35 of a micro-lens ML35 disposed at an upper portion of the subpixel Sbp35 disposed at the center of the shared pixel may not be disposed close to any one side. Micro-lenses ML31 to ML34 and ML36 to ML39 surrounding the subpixel Sbp35 disposed at the center of the shared pixel may have a structure where a highest point thereof is close to the center of the shared pixel.

Based on such a structure, light may concentrate on a center of a shared pixel, and an electrical signal applied from a photodiode may be classified into data having high AF sensitivity and data having a high AF contrast.

Hereinabove, embodiments have been described with reference to the drawings and the specification by using the terms described herein, however the description should not be construed to limit meaning or scope of the inventive concepts defined in the following claims. Therefore, it should be understood by those of ordinary skill in the art that various modifications and other equivalent embodiments may be implemented based on the inventive concepts. Accordingly, the spirit and scope of the inventive concepts may be defined based on the spirit and scope of the following claims.

While the inventive concept has been particularly shown and described with reference to embodiments thereof, it will be understood that various changes in form and details may be made therein without departing from the spirit and scope of the following claims.

What is claimed is:

1. An image sensor comprising:
a shared pixel including a plurality of subpixels;
a plurality of micro-lenses respectively disposed at upper portions of the plurality of subpixels; and
a color filter disposed between the shared pixel and the plurality of micro-lenses,
wherein the color filter is configured to pass light of a single color to the shared pixel,
each of the plurality of subpixels comprises two or more photodiodes, and
highest points of each of the plurality of micro-lenses from an upper surface of the color filter are respectively disposed over one of the two or more photodiodes of the plurality of subpixels that are closer to a center of the shared pixel.

2. The image sensor of claim 1, wherein a number of the plurality of subpixels and a number of the plurality of micro-lenses are the same.

3. The image sensor of claim 1, wherein heights of the highest points of the plurality of micro-lenses from the upper surface of the color filter are equal to each other.

4. The image sensor of claim 1, wherein shapes of the plurality of micro-lenses are symmetric with one another with respect to the center of the shared pixel.

5. The image sensor of claim 1, wherein heights of lowest points of the plurality of micro-lenses near the center of the shared pixel are greater than heights of lowest points of the plurality of micro-lenses at an edge of the shared pixel, wherein the heights are from the upper surface of the color filter.

6. An image sensor comprising:
a shared pixel including first to n^{th} subpixels arranged in an N*N form;
N*N number of first to n^{th} micro-lenses respectively disposed at upper portions of the first to n^{th} subpixels arranged in the N*N form; and
a color filter disposed between the shared pixel and the first to n^{th} micro-lenses,
wherein a distance between a highest point of an m^{th} micro-lens from among the first to n^{th} micro-lenses as from an upper surface of the color filter and a center of the shared pixel is shorter than a distance between the center of the shared pixel and a center of an m^{th} subpixel from among the first to n^{th} subpixels that is disposed at a lower portion of the m^{th} micro-lens, and
m is a natural number of 1 or more and n or less, n is a natural number of 4 or more, and N is a natural number of 2 or more.

7. The image sensor of claim 6, wherein each of the first to n^{th} subpixels comprises a plurality of photodiodes.

8. The image sensor of claim 7, wherein a height of one end portion of the m^{th} micro-lens differs from a height of an other end portion of the m^{th} micro-lens, and the heights are from the upper surface of the color filter.

9. The image sensor of claim 7, wherein heights of highest points of the first to n^{th} micro-lenses are equal to each other, and the heights are from the upper surface of the color filter.

10. The image sensor of claim 7, wherein distances between the center of the shared pixel and micro-lenses from among the first to n^{th} micro-lenses which are adjacent to the center of the shared pixel in a diagonal direction are equal to each other.

11. The image sensor of claim 7, wherein distances between the center of the shared pixel and micro-lenses from among the first to n^{th} micro-lenses which are adjacent to the center of the shared pixel in non-diagonal direction are equal to each other.

12. The image sensor of claim 6, wherein the color filter is configured to pass light of a single color.

13. An electronic device comprising:
an image sensor; and
a processor connected to the image sensor and configured to process data of the image sensor,
the image sensor comprising
a first subpixel including a first photodiode and a second photodiode,
a second subpixel including a third photodiode and a fourth photodiode, the second subpixel disposed adjacent to the first subpixel,
a first micro-lens disposed at an upper portion of the first subpixel,
a second micro-lens disposed at an upper portion of the second subpixel, and
a color filter disposed between the first and second subpixels and the first and second micro-lenses,
wherein a highest point of the first micro-lens from an upper surface of the color filter is disposed in a region over the second photodiode,
a highest point of the second micro-lens from the upper surface of the color filter is disposed in a region over the third photodiode, and
the first and second subpixels configure a shared pixel, the second photodiode is disposed closer to a center of the shared pixel than the first photodiode, and the third photodiode is disposed closer to the center of the shared pixel than the fourth photodiode.

14. The electronic device of claim 13, wherein the second photodiode is disposed adjacent to the third photodiode.

15. The electronic device of claim 14, wherein the processor is configured to obtain a first electrical signal, a second electrical signal, a third electrical signal, and a fourth electrical signal respectively from the first photodiode, the second photodiode, the third photodiode, and the fourth photodiode,
the second electrical signal and the third electrical signal are a left-right data pair having high auto focusing (AF) sensitivity, and
the first electrical signal and the fourth electrical signal are a left-right data pair having a high AF contrast.

16. The electronic device of claim 13, wherein a height of the highest point of the first micro-lens and a height of the highest point of the second micro-lens are the same.

17. The electronic device of claim 13, wherein a height of a lowest point of the first micro-lens in a region over the first photodiode and a height of a lowest point of the second micro-lens in a region over the fourth photodiode are the same.

18. The electronic device of claim 17, wherein a height of a lowest point of the first micro-lens in a region over the second photodiode and a height of a lowest point of the second micro-lens in a region over the third photodiode are the same.

19. The electronic device of claim 18, wherein the height of the lowest point of the first micro-lens in the region over the first photodiode is lower than the height of the lowest point of the first micro-lens in the region over the second photodiode are the same.

20. The electronic device of claim 13, wherein the first micro-lens and the second micro-lens are symmetric with each other with respect to a contact point between the first subpixel and the second subpixel.
